(19) United States
(12) Patent Application Publication
(10) Pub. No.: US 2025/0219000 A1
(43) Pub. Date: Jul. 3, 2025

(54) SEMICONDUCTOR PACKAGE

(71) Applicant: SAMSUNG ELECTRONICS CO., LTD., Suwon-si (KR)

(72) Inventor: Junghoon KANG, Suwon-si (KR)

(73) Assignee: SAMSUNG ELECTRONICS CO., LTD., Suwon-si (KR)

(21) Appl. No.: 18/775,867

(22) Filed: Jul. 17, 2024

(30) Foreign Application Priority Data
Jan. 2, 2024 (KR) 10-2024-0000198

(51) Int. Cl. H01L 23/00; H01L 23/48; H01L 25/065; H10B 80/00

(52) U.S. Cl. CPC H01L 24/16; H01L 24/05; H01L 24/13; H01L 24/32; H01L 24/73; H01L 25/0657; H01L 23/481; H01L 24/09; H01L 24/17; H01L 24/33; H01L 2224/0401; H01L 2224/05557; H01L 2224/05647; H01L 2224/09181; H01L 2224/13198; H01L 2224/16146; H01L 2224/17181; H01L 2224/32145; H01L 2224/32501; H01L 2224/33181; H01L 2224/73204; H10B 80/00

(57) ABSTRACT

A semiconductor package includes an insulating layer; first pads respectively surrounded by the insulating layer; second pads electrically connected to the first pads; solders between and connected to the first pads and the second pads, and respectively surrounded by the insulating layer, and margin portions including an insulating material, surrounding the solders, and respectively surrounded by the insulating layer.

### CROSS-REFERENCE TO RELATED APPLICATION

This application claims priority to Korean Patent Application No. 10-2024-0000198, filed on Jan. 2, 2024, in the Korean Intellectual Property Office, the disclosure of which is incorporated by reference herein in its entirety.

### BACKGROUND

The present disclosure relates to a semiconductor package.

Generally, semiconductor chips may be implemented as semiconductor packages, such as wafer level packages (WLP) or panel level packages (PLP), and semiconductor packages may be used as electronic components of devices.

A semiconductor package may include a redistribution layer to electrically connect a semiconductor chip to a device or printed circuit board. The redistribution layer may have a redistribution structure that extends horizontally and is implemented more finely than an interconnection of an interconnection layer of a general printed circuit board layer.

According to the trend of miniaturization and high performance of semiconductor packages, it is necessary to develop system-in-package (SiP) technology of embedding a plurality of semiconductor chips performing different functions in a single package. To form fine interconnections connecting semiconductor chips within a package, a technology of forming a through-silicon via (TSV) and bonding semiconductor chips to each other through a bonding pad has been used.

A pad has a conductive structure for providing a vertical electrical connection path for a semiconductor chip and/or a redistribution layer and may be vertically connected to a bump. As a width or pitch of each of the plurality of pads decreases, the degree of integration of the electrical connection paths of the plurality of pads may increase.

### SUMMARY

One or more embodiments provide a semiconductor package that may have an improved degree of integration of electrical connection paths provided by a plurality of pads or improved reliability of the electrical connection paths.

According to an aspect of the present disclosure, a semiconductor package is provided and includes; an insulating layer; first pads respectively surrounded by the insulating layer; second pads electrically connected to the first pads; solders between and connected to the first pads and the second pads, and respectively surrounded by the insulating layer; and margin portions including an insulating material, surrounding the solders, and respectively surrounded by the insulating layer.

According to an aspect of the present disclosure, a semiconductor package is provided and includes: an insulating layer; first pads respectively surrounded by the insulating layer; second pads electrically connected to the first pads; solders between and connected to the first pads and the second pads, and respectively surrounded by the insulating layer; and an underfill on an upper surface of the insulating layer and surrounding each of the second pads, wherein a level of lower surfaces of the second pads is lower than a level of the upper surface of the insulating layer.

According to an aspect of the present disclosure, a semiconductor package is provided and includes: semiconductor chips; an insulating layer between the semiconductor chips; first pads respectively surrounded by the insulating layer; epoxy solders surrounded by the insulating layer and surrounding each of the first pads, the epoxy solders including solder particles and an epoxy resin; an underfill between the semiconductor chips; and second pads surrounded by the underfill and compressing the epoxy solders on the first pads.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a cross-sectional view illustrating a semiconductor package according to an embodiment of the present disclosure;

FIG. 2A is an enlarged view of a portion A of the semiconductor package of FIG. 1;

FIG. 2B is an enlarged view of a portion B of the semiconductor package of FIG. 1;

FIG. 2C is a plan view illustrating a cross-section of a semiconductor package according to an embodiment of the present disclosure;

FIG. 3 is a cross-sectional view illustrating a semiconductor package according to an embodiment of the present disclosure;

FIG. 4 is a cross-sectional view illustrating a state before first and second pads of a semiconductor package are connected according to an embodiment of the present disclosure;

FIGS. 5A to 5F are cross-sectional views illustrating a semiconductor package according to an embodiment of the present disclosure;

FIGS. 6A to 7C are cross-sectional views illustrating a method of manufacturing a semiconductor package according to an embodiment of the present disclosure; and

FIG. 7D is a cross-sectional view illustrating a structure in which semiconductor packages are mounted on an interposer according to an embodiment of the present disclosure.

### DETAILED DESCRIPTION

In the following detailed description, reference is made to the accompanying drawings that show, by way of illustration, non-limiting example embodiments of the present disclosure. These non-limiting example embodiments are described in sufficient detail to enable those skilled in the art to practice the present disclosure. It is to be understood that the various embodiments of the present disclosure, although different, are not necessarily mutually exclusive. For example, a certain feature, structure, or characteristic described herein in connection with one embodiment may be implemented within other embodiments without departing from the spirit and scope of the present disclosure. In addition, it is to be understood that the location or arrangement of individual elements within each disclosed embodiment may be modified without departing from the spirit and scope of the present disclosure. The following detailed description is, therefore, not to be taken in a limiting sense, and the scope of the present disclosure includes a full range of equivalents. In the drawings, like numerals refer to the same or similar functionality throughout the several views.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

Hereinafter, non-limiting example embodiments of the present disclosure will be described in detail with reference to the accompanying drawings such that they may be easily practiced by those skilled in the art to which the present disclosure pertains.

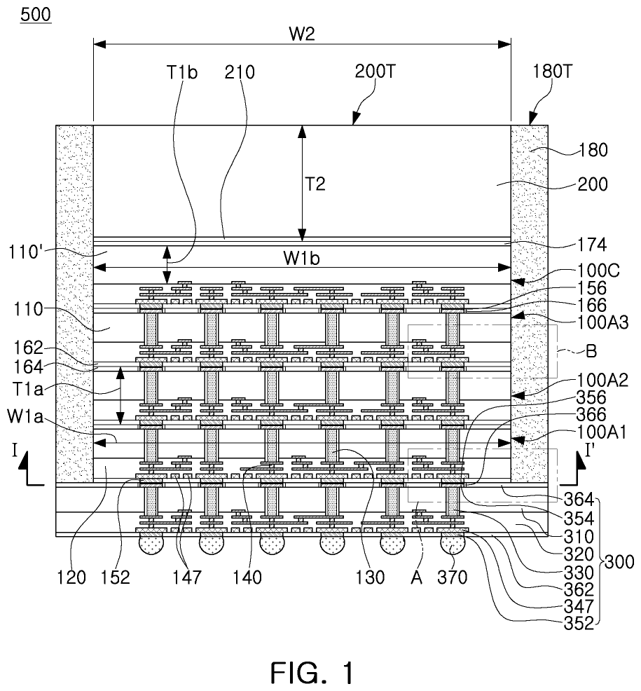

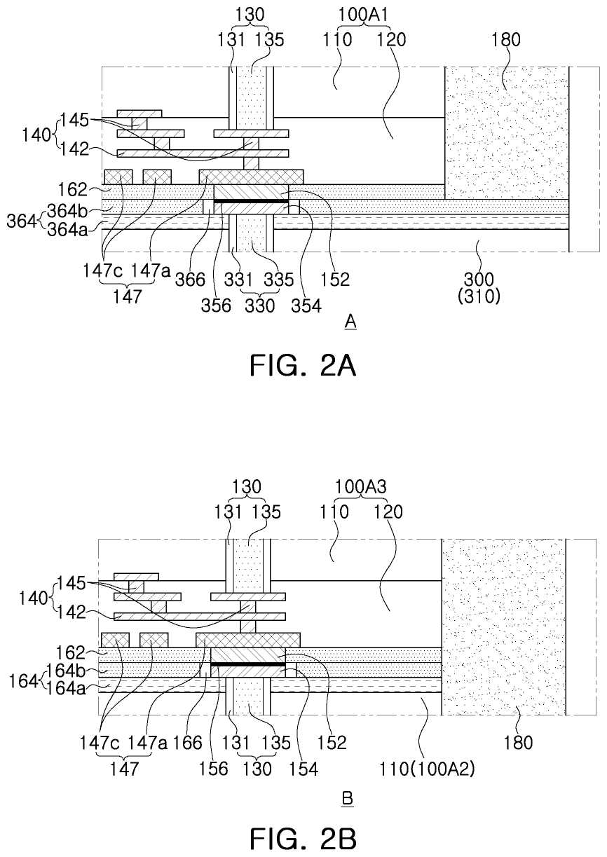

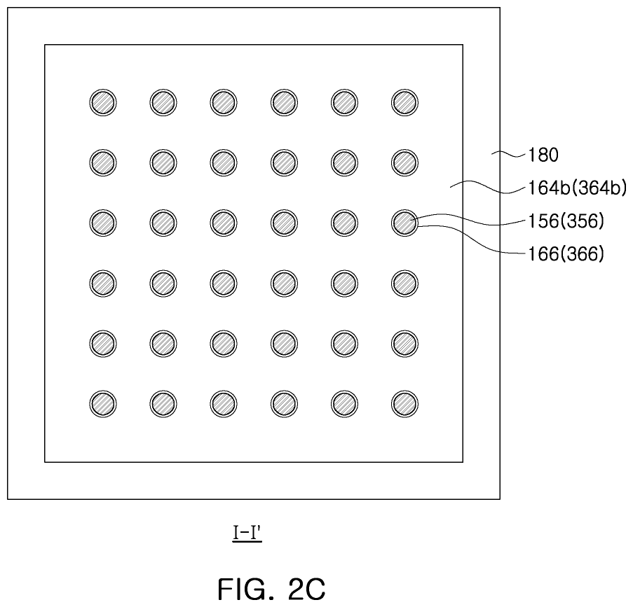

FIG. 1 is a cross-sectional view illustrating a semiconductor package 500 according to an embodiment of the present disclosure, FIG. 2A is an enlarged view illustrating a portion A of the semiconductor package 500 of FIG. 1, FIG. 2B is an enlarged view illustrating a portion B of the semiconductor package 500 of FIG. 1, and FIG. 2C is a plan view illustrating a cross-section of the semiconductor package 500 of FIG. 1 taken along line I-I′ of FIG. 1.

Referring to FIGS. 1, 2A, 2B, and 2C, the semiconductor package 500 according to an embodiment of the present disclosure may include at least one of a plurality of semiconductor chips 100A1, 100A2, 100A3, and 100C and may further include a semiconductor chip 300 disposed below the plurality of semiconductor chips 100A1, 100A2, 100A3, and 100C. Each of the plurality of semiconductor chips 100A1, 100A2, 100A3, and 100C may include a semiconductor substrate (e.g., a semiconductor substrate 110 or a semiconductor substrate 110′), a device layer 120, and conductive patterns 147 and may provide an arrangement space for an underfill 162 and a second pads 152. Each of the plurality of semiconductor chips 100A1, 100A2, and 100A3 may include a through-electrodes 130 and may provide an arrangement space for an insulating layer 164 and a first pads 154. FIG. 1 illustrates a structure including four semiconductor chips (e.g., the semiconductor chips 100A1, 100A2, 100A3, and 100C), but the number of semiconductor chips is not particularly limited.

The plurality of semiconductor chips 100A1, 100A2, 100A3, and 100C may be memory chips. For example, the memory chips may be volatile memory chips (e.g., dynamic random access memory (DRAM) or static random access memory (SRAM)) or nonvolatile memory chips (e.g., phase-change random access memory (PRAM), magnetoresistive random access memory (MRAM), ferroelectric random access memory (FeRAM), or resistive random access memory (RRAM)). Alternatively, some of the plurality of semiconductor chips 100A1, 100A2, 100A3, and 100C may be memory chips and others may be logic chips. The logic chip may be, for example, a microprocessor, an analog element, or a digital signal processor, and may control the operation of memory chips. For example, a combination of the plurality of semiconductor chips 100A1, 100A2, 100A3, and 100C may be a high bandwidth memory (HBM) DRAM, and the semiconductor chip 300 may be a buffer chip of HBM.

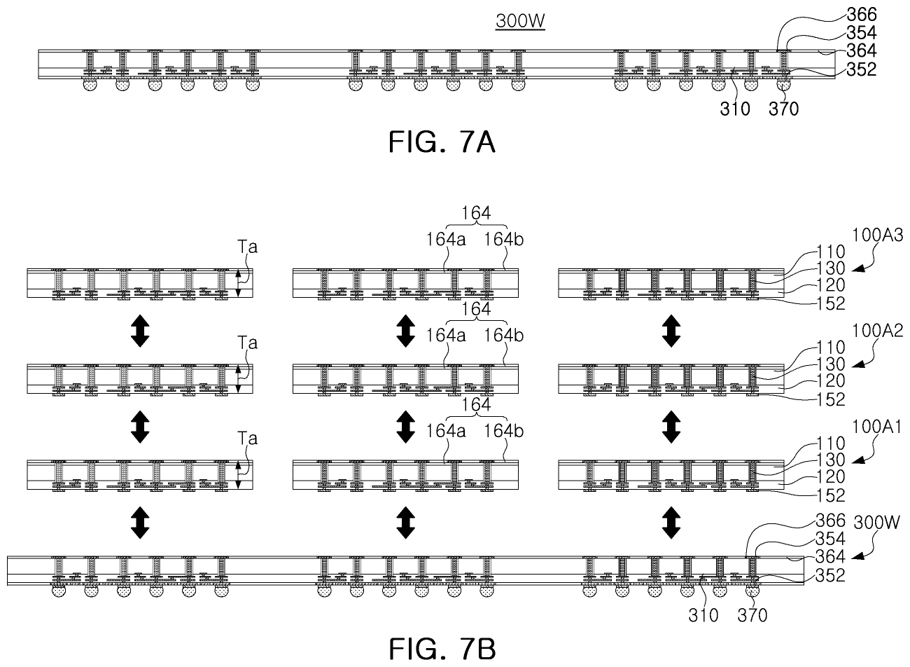

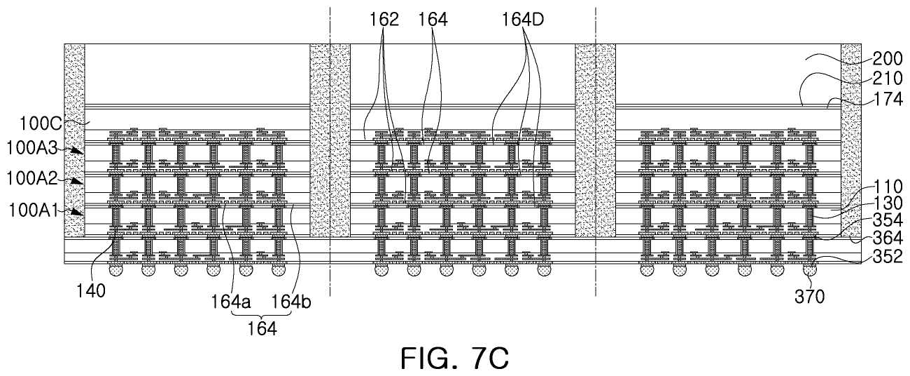

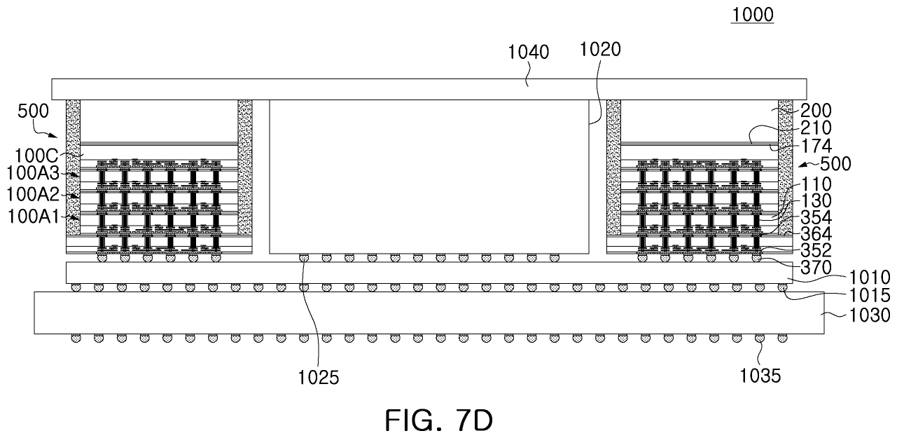

The semiconductor chip 300 may include a second pads 352 disposed on a lower surface thereof and a first pads 354 disposed on an upper surface thereof. For example, the semiconductor chip 300 may have a width (or an area) greater than widths W1a and W1b (or areas) of the plurality of semiconductor chips 100A1, 100A2, 100A3, and 100C. The semiconductor chip 300 may include a semiconductor substrate 310 and an interconnection circuit connecting the second pads 352 to the first pads 354 within the semiconductor substrate 310. Connection bumps 370 may be attached to the second pads 352 of the semiconductor chip 300. The connection bump 370 may be, for example, a solder ball or a conductive bump. The connection bumps 370 may electrically connect the semiconductor package 500 to a printed circuit board (PCB) (e.g., a printed circuit board 1030 in FIG. 7D), such as a mother board. Alternatively, the connection bumps 370 may be electrically connected to an interposer (e.g., an interposer 1010 in FIG. 7D) for a redistribution of a lower side. Depending on the embodiment, the semiconductor chip 300 may be redisposed with the interposer (e.g., the interposer 1010 in FIG. 7D).

The semiconductor substrate 110 and the semiconductor substrate 110′ may include a semiconductor, such as silicon. For example, the semiconductor substrate 110 may include various impurity regions for individual devices and a device isolation structure, such as a shallow trench isolation (STI) structure. The semiconductor is not limited to silicon and may include at least one from among germanium, silicon carbide (SiC), gallium arsenide (GaAs), indium arsenide (InAs), and indium phosphide (InP). For example, the device may include a planar metal oxide semiconductor field effect transistor (MOSFET), a FinFET in which an active region has a fin structure, a multi-bridge channel FET™ (MBCFET™) including a plurality of channels stacked vertically on an active region, a gate-all-around transistor, or a vertical FET (VFET), but is not limited thereto. The semiconductor substrate 310 may be implemented in substantially the same manner as the semiconductor substrate 110.

Each of the through-electrodes 130 may have a pillar structure penetrating through the semiconductor substrate 110. The through-electrodes 130 may not penetrate through the semiconductor substrate 110′. An upper end of the through-electrodes 130 may be connected to the first pads 154, and a lower end thereof may be electrically connected to the second pads 152 through an interconnection structure 140. The through-electrodes 130 may each include a via plug 135 and an insulating liner 131 surrounding the via plug 135. The insulating liner 131 may electrically separate the via plug 135 from the semiconductor substrate 110. The semiconductor chip 300 may include through-electrodes 330 that may each include an insulating liner 331 and a via plug 135. The through-electrodes 330, and the insulating liner 331 and the via plug 335 thereof, of the semiconductor chip 300 may be implemented in substantially the same manner as the through-electrodes 130, and the insulating liner 131 and the via plug 135 thereof.

Each device layer 120 may include an interconnection structure 140 connected to a plurality of individual devices formed on a front (lower) surface of the semiconductor substrate 110 or the semiconductor substrate 110′. The interconnection structure 140 may include one or more interconnection layers 142 and one or more interconnection vias 145. For example, the interconnection structure 140 may have a structure in which a plurality of interconnection layers 142 are stacked in a vertical direction, and may include a plurality of interconnection vias 145 electrically connecting the plurality of interconnection layers 142 in the vertical direction. The interconnection structure 140 may be electrically connected to the second pads 152 disposed below the device layer 120. The interconnection layers 142 and the interconnection vias 145 may include at least one from among copper (Cu), copper alloy, aluminum (Al), and aluminum alloy. The metal material is not limited thereto and may be implemented as at least one from among nickel (Ni), gold (Au), cobalt (Co), tantalum (Ta), tellurium (Te), titanium (Ti), tungsten (W), and alloys thereof (e.g. TiN or TaN). A space in the device layer 120 in which the interconnection structure 140 is not disposed may be filled with an insulating layer. For example, the insulating layer may include at least one from among silicon oxide (SiO), silicon nitride (SiN), silicon oxynitride (SiON), silicon oxycarbide (SiOC), and silicon carbonitride (SiCN). The semiconductor chip 300 may include a device layer 320, and the device layer 320 of the semiconductor chip 300 may be implemented in substantially the same manner as the device layer 120.

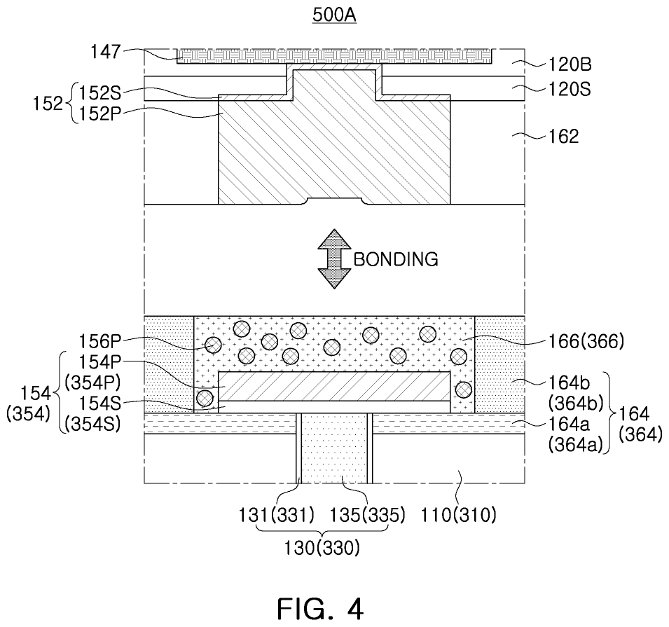

The device layer 120 may include a support insulating layer 120S (refer to FIG. 4) and a device layer 120B (refer to FIG. 4). For example, each of the support insulating layer 120S and the device layer 120B may include at least one from among SiO₂, SiN, SiCN, and tetraethoxysilane (TEOS), and the support insulating layer 120S may include an insulating material (e.g., SiN) different from the insulating layer (e.g. SiO₂) of the device layer 120B. The support insulating layer 120S may surround an upper portion of each of the second pads 152. That is, the second pads 152 may penetrate through the support insulating layer 120S to be connected to the conductive patterns 147, or conductive patterns 347 of the semiconductor chip 300.

The conductive patterns 147 may be disposed on a front surface (a lower surface) of the device layer 120, and the conductive patterns 347 may be disposed on a front surface (a lower surface) of the device layer 320. The conductive patterns 147 may be electrically connected between the interconnection layer 142 of the interconnection structure 140 and the second pads 152, and may be thicker than the interconnection layer 142. The conductive patterns 347 may be electrically connected between an interconnection layer of an interconnection structure, within the device layer 320, and the second pads 352, and may be thicker than the interconnection layer 142.

For example, the conductive patterns 147 (and the conductive patterns 347) and the interconnection layer 142 (and the interconnection layer of the semiconductor chip 300) may include the same material (e.g., aluminum (Al)), but are not limited thereto. The conductive patterns 147 and the conductive patterns 347 may support the second pads 152 and the second pads 352 downwardly, respectively, and as a thickness of the conductive patterns 147 and the conductive patterns 347 increases, the conductive patterns 147 and the conductive patterns 347 may support the second pads 152 and the second pads 352, respectively more strongly downwardly and may form electrical connection paths based on the second pads 152 and the second pads 352, respectively, more efficiently.

For example, the conductive patterns 147 may include at least one from among a pad pattern 147a and a dummy pattern 147c. The pad pattern 147a may be connected to the second pads 152 and support the second pads 152 downwardly. A shape of the pad pattern 147a may be substantially the same as a shape of the second pads 152, and a size of the pad pattern 147a may be slightly greater than a size the second pads 152. The dummy pattern 147c may be spaced apart from the second pads 152 and may provide a ground. The dummy pattern 147c may improve stacking stability (e.g., delamination prevention performance) of the conductive pattern 147.

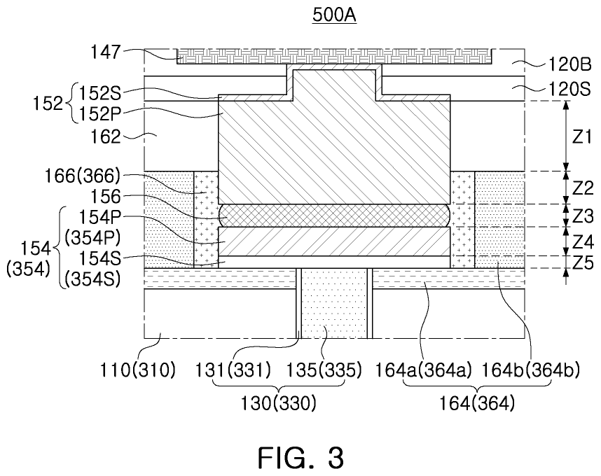

FIG. 3 is a cross-sectional view illustrating a semiconductor package 500A according to an embodiment of the present disclosure and may be an enlarged view of the portion A and the portion B of the semiconductor package of FIGS. 2A and 2B, but a specific form of the semiconductor package 500A may be different from a specific form of the semiconductor package 500 of FIGS. 1, 2A, 2B, and 2C.

Referring to FIGS. 1 to 3, the semiconductor package 500 and the semiconductor package 500A according to an embodiment of the present disclosure may include first pads 154, first pads 354, second pads 152, second pads 352, an insulating layer 164b, an insulating layer 364b, margin portions 166, margin portions 366, solders 156, solders 356, an underfill 162, and an underfill 362. The first pads 154, the second pads 152, the insulating layer 164b, the margin portions 166, the solders 156, and the underfill 162 may be disposed between the plurality of semiconductor chips 100A1, 100A2, 100A3, 100C, 300, but are not limited thereto. The first pads 354, the second pads 352, the insulating layer 364b, the margin portions 366, the solders 356, and the underfill 362 may be disposed between the semiconductor chip 300 and an interposer (e.g., the interposer 1010 in FIG. 7D), but are not limited thereto.

The second pads 152 may be arranged on front surfaces (or lower surfaces) of the plurality of semiconductor chips 100A1, 100A2, 100A3, and 100C, respectively, and may provide electrical paths for the outside of each of the plurality of semiconductor chips 100A1, 100A2, 100A3, and 100C. The outside of each of the semiconductor chips 100A2, 100A3, and 100C may include the first pads 154 of the semiconductor chips 100A1, 100A2, and 100A3 immediately below. That is, the second pads 152 of one semiconductor chip are connected to the first pads 154 of another semiconductor chip, thereby providing an electrical connection path between the plurality of semiconductor chips 100A1, 100A2, 100A3, and 100C. The first pads 154 may be arranged on rear surfaces (upper surfaces) of the plurality of semiconductor chips 100A1, 100A2, and 100A3 and may be connected between the second pads 152 and the through-electrodes 130.

The front surface (lower surface) and the rear surface (upper surface) of each of the second pads 152 and the first pads 154 may be polygonal or circular and may have a width greater than a line width of the interconnection of the interconnection layer 142. Each of the second pads 152 and the first pads 154 may include a metal material that may be bonded to each other, while having high conductivity, such as copper (Cu) or a copper alloy. The metal material is not limited to copper and may be implemented as at least one from among aluminum (Al), nickel (Ni), gold (Au), cobalt (Co), tantalum (Ta), tellurium (Te), titanium (Ti), and tungsten (W). For example, the second pads 152 and the first pads 154 may be temporarily bonded to be in direct contact and then may be firmly bonded to each other by mutual diffusion of copper through a high temperature annealing process. The first pads 354 may be implemented in substantially the same manner as the first pads 154, and the second pads 352 may be implemented in substantially the same manner as the plurality of second pads 152.

The underfill 162 may be disposed on the upper surface of the insulating layer 164 and surround the second pads 152, and the insulating layer 164 may surround the first pads 154. The underfill 162 and the rear surfaces (the upper surfaces) of the second pads 152 may be coplanar, and the insulating layer 164 and the front surfaces (the lower surfaces) of the first pads 154 may be coplanar.

The underfill 162 may be a non-conductive film (NCF), but is not limited thereto. For example, the underfill 162 may include at least one from among epoxy resin, silica (SiO₂), and acrylic copolymer, or combinations thereof. Depending on a specific material or process of the underfill 162, the underfill 162 may protrude slightly compared to side surfaces of the plurality of semiconductor chips 100A1, 100A2, 100A3, 100C, and 300. The underfill 362 may be implemented in substantially the same manner as the underfill 162.

The insulating layer 164 may include an insulating material advantageous for forming a plurality of cavities in which the first pads 154 are disposed. The insulating layer 164 may include a material that may be included in a solder resist layer of a PCB and may provide a plurality of cavities formed by photolithography. For example, the insulating layer 164 may include a different insulating material than an insulating material of the underfill 162. For example, the insulating layer 164 may include at least one from among a build-up film, photosensitive polyimide (PSPI), and photo imagable dielectric (PID). For example, the build-up film may be Ajinomoto Build-up Film (ABF). The insulating layer 364 may be implemented in substantially the same manner as the insulating layer 164.

For example, the insulating layer 164 may include a rear insulating layer 164a and an insulating layer 164b, and the insulating layer 364 may include a rear insulating layer 364a and an insulating layer 364b. The insulating layer 164b and the insulating layer 364b may be disposed on the rear surfaces (the upper surfaces) of the rear insulating layer 164a and the rear insulating layer 364a, respectively, and the rear insulating layer 164a and the rear insulating layer 364a may be disposed on the rear surfaces (the upper surfaces) of the semiconductor substrate 110 and the semiconductor substrate 310, respectively. The rear insulating layer 164a may prevent unwanted electrical connection between the first pads 154 and the semiconductor substrate 110, and the rear insulating layer 364a may prevent unwanted electrical connection between the first pads 354 and the semiconductor substrate 310. For example, the rear insulating layer 164a and the rear insulating layer 364a may include silicon nitride or silicon oxynitride, and the insulating layer 164b and the insulating layer 374b may include at least one from among a build-up film, photosensitive polyimide (PSPI), and PID.

The plurality of cavities formed in the insulating layer 164b and the insulating layer 364b may have a width greater than a width of each of the first pads 154 and/or the first pads 354. The margin portions 166 (or the margin portions 366) are disposed within the plurality of cavities, may have a width corresponding to a difference in width between the plurality of cavities and the first pads 154 (or the first pads 354), may respectively surround the first pads 154, and may be respectively surrounded by the insulating layers 164b and 364b. The margin portions 366 may be implemented in substantially the same manner as the margin portions 166.

The solders 156 may be connected between the first pads 154 and the second pads 152 and may be respectively surrounded by the insulating layer 164b. The solders 356 may be connected between the first pads 354 and the second pads 352 and may be respectively surrounded by the insulating layer 364b.

Each of the solders 156 and the solders 356 may include a metal material (e.g., solder paste, tin (Sn), lead (Pb), bismuth (Bi) and alloys thereof) having a lower melting point than a melting point of the first pads 154, the first pads 354, the second pads 152, and the second pads 352, and may be fixed between the first pads 154 and the second pads 152 or between the first pads 354 and the second pads 352 by a reflow process or a thermal compression bonding (TCB) process.

As the size of each of the solders 156 (or the solders 356) decreases, a possibility that an electrical short will occur to an adjacent solder among the solders 156 (or the solders 356) may decrease, and thus, an interval between the solders 156 (or the solders 356) may also decrease. That is, as the size of each of the solders 156 (or the solders 356) decreases, the interval (or pitch) between the first pads 154 (or the first pads 354) may decrease and the interval (or pitch) between the second pads 152 (or the second pads 352) may also decrease. As the interval (or pitch) decreases, the width of each of the first pads 154 (or the first pads 354) and the second pads 152 (or the second pads 352) may advantageously narrow. As the interval (or pitch) and/or width decreases, the degree of integration of a plurality of electrical paths provided between the first pads 154 (or the first pads 354) and the second pads 152 (or the second pads 352) may increase.

Meanwhile, as the size of each of the solders 156 (or the solders 356) decreases, the difficulty of securing an area in which the solders 156 (or the solders 356) are in contact with the first pads 154 (or the first pads 354) and the second pads 152 (or the second pads 352) may increase and the difficulty of securing reliability of electrical paths based on the solders 156 (or the solders 356) may also increase.

Since the first pads 154 (or the first pads 354) and the second pads 152 (or the second pads 352) may press the solders 156 (or the solders 356) vertically within the plurality of cavities surrounded by the insulating layer 164b (or the insulating layer 364b), although the solders 156 (or the solders 356) have a small volume, the area in which the solders 156 (or the solders 356) are in contact with the first pads 154 (or the first pads 354) and the second pads 152 (or the second pads 352) may be stably secured and the reliability of electrical paths (e.g., impedance stability, a reduction in equivalent series resistance (ESR), signal integrity, power integrity, etc.) based on the solders 156 (or the solders 356) may also be stably secured. In addition, since it may be advantageous for the solders 156 (or the solders 356) to have small sizes, the interval (or pitch) between or the width of the first pads 154 (or the first pads 354) and the second pads 152 (or the second pads 352) may be advantageously reduced and the degree of integration of a plurality of electrical connection paths (e.g., paths through which at least one of data signals, control signals, power signals, and ground signals passes) provided between the first pads 154 (or the first pads 354) and the second pads 152 (or the second pads 352) may increase.

The margin portions 166 may provide lateral available space required for the solders 156 according to vertical compression of the solders 156, and the margin portions 366 may provide lateral available space required for the solders 356 according to vertical compression of the solders 356. Accordingly, the first pads 154 and the second pads 152 may stably press the solders 156 vertically and the solders 156 may have a large contact area compared to the volume, and the first pads 354 and the second pads 352 may stably press the solders 356 vertically and the solders 356 may have a large contact area compared to the volume. Accordingly, the degree of integration and reliability of the electrical connection paths of the solders 156 and the solders 356 may increase. For example, the margin portions 166 may separate the first pads 154 from the insulating layers 164b, and the margin portions 366 may separate the first pads 354 from the insulating layer 364b.

Since a level of the lower surfaces of the second pads 152 (or the second pads 352) may be located lower than the upper surface of the insulating layer 164b (or the insulating layer 364b), the solders 156 (or the solders 356) may be prevented from significantly overflowing onto the upper surface of the insulating layer 164b (or the insulating layer 364b), while being pressed vertically. Thus, the solders 156 and the solders 356 may have a large contact area relative to their volume and the degree of integration and reliability of the electrical connection paths of the solders 156 and the solders 356 may increase.

For example, a thickness (Z1+Z2) of each of the second pads 152 (or the second pads 352) may be greater than a thickness (Z4+Z5) of each of the first pads 154 (or the first pads 354). The thickness (Z4+Z5) of each of the first pads 154 (or the first pads 354) may be less than a thickness (Z2+Z3+Z4+Z5) of the insulating layer 164b (or the insulating layer 364b).

Since the solders 156 (or the solders 356) may not overflow onto the upper surface of the insulating layer 164b (or the insulating layer 364b), the underfill 162 may be spaced apart from the solders 156 (or the solders 356). A thickness Z3 of each of the solders 156 (or the solders 356 may be less than the thickness (Z2+Z3+Z4+Z5) of the insulating layer 164b (or the insulating layer 364b) and may be less than the thickness (Z4+Z5) of each of the first pads 154 (or the first pads 354), but is not limited thereto.

Values Z1, Z2, Z3, Z4, and Z5 may be measured as average values in a cross-section of the semiconductor package and may be applied to analysis using at least one from among transmission electron microscopy (TEM), atomic force microscope (AFM), scanning electron microscope (SEM), optical microscopy, and surface profiler. Values Z1, Z2, Z3, Z4, and Z5 may be measured by visual checking or image processing (e.g., identification of pixels based on a color or brightness of pixels, filtering of pixel values for pixel identification efficiency, integrating distances between identified pixels, etc.).

FIG. 4 illustrates a state before the first and second pads of the semiconductor package 500A are connected according to an embodiment of the present disclosure. Referring to FIG. 4, before the second pads 152 are connected, a plurality of solder particles 156P and the margin portions 166 (or the margin portions 366) may be mixed with each other. For example, a combination structure of the plurality of solder particles 156P and the margin portions 166 (or the margin portions 366) may be epoxy solders, may be surrounded by the insulating layer 164b (or the insulating layer 364b), and may seal the first pads 154 (or the first pads 354).

The epoxy solders may have a structure in which an epoxy resin and the plurality of solder particles 156P are mixed. Since the epoxy resin may have higher flexibility than flexibility of general insulating materials, a shape of the epoxy resin may be flexibly deformed when the epoxy resin is pressed downwardly by the second pads 152. An insulating material of the margin portions 166 (or the margin portions 366) is not limited to epoxy resin and may be an insulating material different from the insulating material (e.g., a build-up film, PSPI, and PID) of the insulating layer 164b (or the insulating layer 364b).

Meanwhile, among the plurality of solder particles 156P, solder particles vertically overlapping the second pads 152 may be compressed vertically by the second pads 152. Accordingly, the combination structure (epoxy solder) of the plurality of solder particles 156P and the margin portions 166 (or the margin portions 366) may have an in-between region between the first pads 154 (or the first pads 354) and the second pads 152 (or the second pads 352) and a margin region (corresponding to the margin portion 166 or the margin portion 366 in FIG. 3) surrounding the in-between region, and a density of solder particles in the in-between region may be higher than a density of solder particles of the margin region. Since the density of the solder particles in the in-between region is high, the in-between region may correspond to the solders 156 (or the solders 356) of FIG. 1 and FIG. 3.

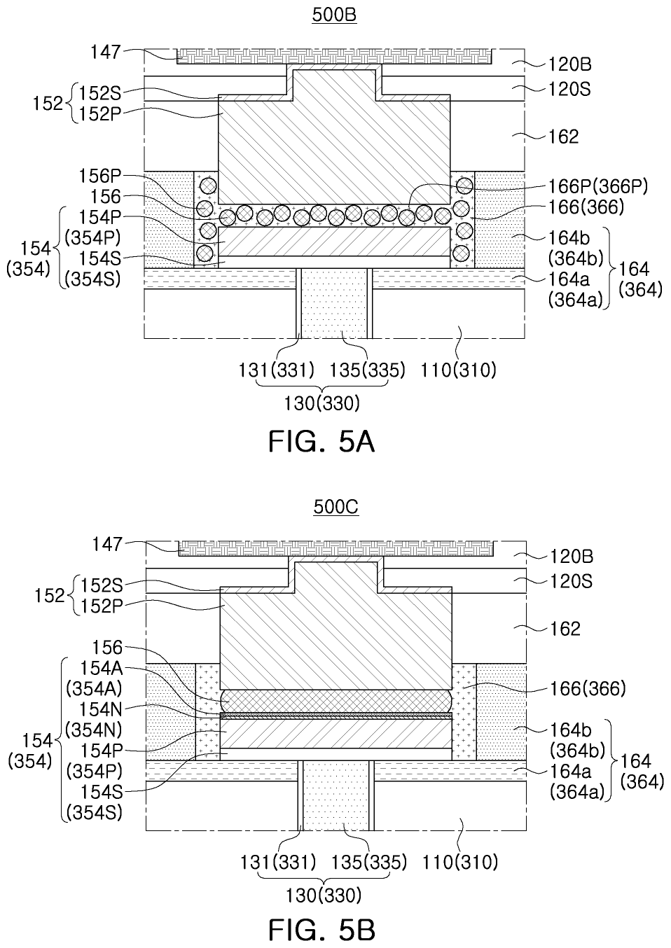

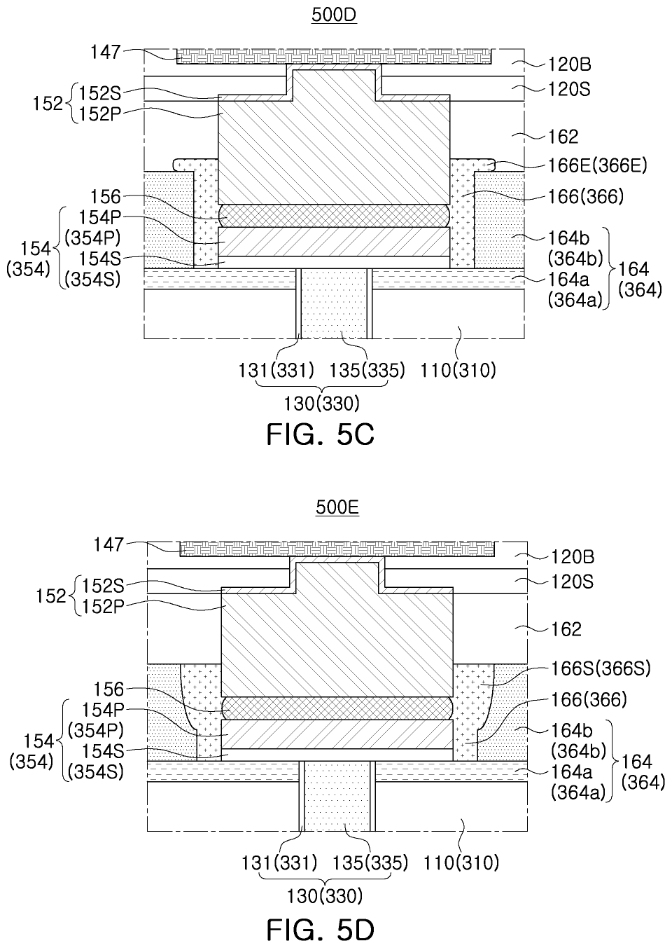

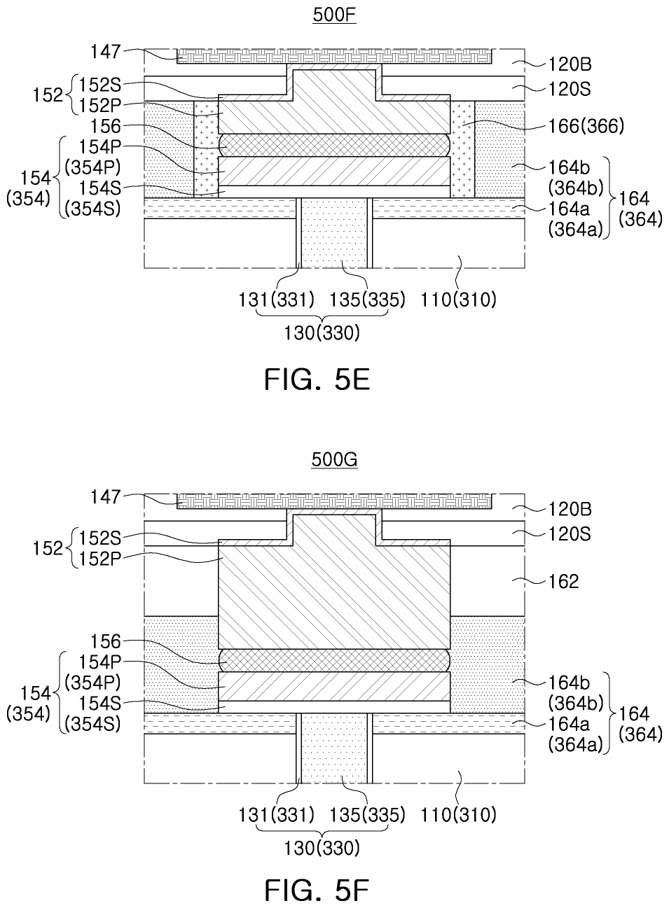

FIGS. 5A to 5F illustrate various structures of a semiconductor package 500B, a semiconductor package 500C, a semiconductor package 500D, a semiconductor package 500E, a semiconductor package 500F, and a semiconductor package 500G according to embodiments of the present disclosure.

Referring to FIG. 5A, the semiconductor package 500B according to an embodiment of the present disclosure may have a structure in which the plurality of solder particles 156P and the margin portions 166 (or the margin portions 366) are mixed, even after the plurality of solder particles 156P and the margin portions 166 (or the margin portions 366) are compressed by the second pads 152. In the structure, a region corresponding to the solders 156 (or the solders 356) of the semiconductor package 500A of FIG. 3 may have a high solder particle density, and in the structure, a region corresponding to the margin portions 166 (or the margin portions 366) of the semiconductor package 500A of FIG. 3 may have a low solder particle density.

Referring to FIG. 5B, first pads 154 (or first pads 354) of the semiconductor package 500C according to an embodiment of the present disclosure may include at least one from among seed layers 154S and 354S, pads 154P and 354P, first pad surface layers 154N and 354N, and second pad surface layers 154A and 354A. A second pads 152 may include at least one from among a seed layer 152S and a pad 152P.

The seed layers 152S, 154S, and 354S may assist in forming the pads 152P, 154P, and 354P. For example, the seed layers 152S, 154S, and 354S may be formed by sputtering, and the pads 152P, 154P, and 354P may be formed on the seed layers 152S, 154S, and 354S by electroless plating. The seed layers 152S, 154S, and 354S may include a different material (e.g., Ti, TiW) than a material of the pads 152P, 154P, and 354P, the first pad surface layers 154N and 354N and the second pad surface layers 154A and 354A. The pads 154P and 354P may include copper (Cu) or an alloy of copper, the first pad surface layers 154N and 354N may include nickel (Ni) or an alloy of nickel, and the second pad surface layers 154A and 354A may include gold (Au) or an alloy of gold. For example, the pads 154P and 354P, the first pad surface layers 154N and 354N, and the second pad surface layers 154A and 354A may be sequentially formed by electroless plating.

Referring to FIG. 3, the first pad surface layers 154N and 354N and the second pad surface layers 154A and 354A of FIG. 5B may be omitted depending on the embodiment, so the solders 156 may be in direct contact with copper of the first pads 154 (or the first pads 354) or a copper alloy (e.g., the pads 154P and 354P) and may be in direct contact with copper of the second pads 152 or a copper alloy (e.g., the pad 152P). For example, copper or the copper alloy may have high wettability for a plurality of solder particles of epoxy solders, so that electrical connection paths may be stably formed based on epoxy solders.

Referring to FIG. 5C, the margin portions 166 and the margin portions 366 of the semiconductor package 500D according to an embodiment of the present disclosure may have portions 166E and 366E, respectively overflowing onto upper surfaces of the insulating layer 164b and the insulating layer 364b, respectively. The occurrence of the portions 166E and 366E, that are overflowing, may vary depending on how much the plurality of cavities of the insulating layer 164b and the insulating layer 364b are filled by the combination structure (epoxy solders) of the plurality of solder particles 156P and the margin portions 166 (or the margin portions 366) in FIG. 4.

Referring to FIG. 5D, the margin portions 166 and the margin portions 366 of the semiconductor package 500E according to an embodiment of the present disclosure may have portions 166S and 366S, respectively, that extrude on upper portions of side surfaces of the insulating layer 164b and the insulating layer 364b, respectively. The occurrence of the portions 166S and 366S, that are extruding, may vary depending on how much the plurality of cavities of the insulating layer 164b and the insulating layer 364 are filled by the combination structure (epoxy solder) of the plurality of solder particles 156P and the margin portions 166 (or the margin portions 366) of FIG. 4. Whether the portions 166E and 366E of FIG. 5C and the portions 166S and 366S of FIG. 5D occur may vary depending on the insulating material of the margin portions 166, the margin portions 366, the insulating layer 164b, and the insulating layer 364b.

Referring to FIG. 5E, the semiconductor package 500F according to an embodiment of the present disclosure may have a structure in which the underfill 162 of FIG. 3 is omitted. A space occupied by the underfill 162 of FIG. 3 may be redisposed with a portion of the insulating layer 164b (or the insulating layer 364b) and a portion of the margin portions 166 (or the margin portions 366). The insulating layer 164b and the insulating layer 364b of FIG. 5E are not limited to one layer. For example, the insulating layer 164b and the insulating layer 364b of FIG. 5E may have a structure in which a plurality of insulating layers are vertically coupled by covalent bonds (e.g., Si—O—Si bonds). In addition, the thickness of the second pads 152 may be substantially the same as the thickness of the first pads 154 and the first pads 354 and may be less than the thickness of the second pads 152 in FIG. 3. The margin portions 166 and the margin portions 366 may provide a laterally available space required for the solders 156 according to vertical compression of the solders 156. Accordingly, the first pads 154, the first pads 354, and the second pads 152 may stably press the solders 156 vertically and the solders 156 may have a large contact area compared to their volumes. Accordingly, the degree of integration and reliability of the electrical connection paths of the solders 156 may increase.

Referring to FIG. 5F, the semiconductor package 500G according to an embodiment of the present disclosure may have a structure in which the margin portions 166 and the margin portions 366 of FIG. 3 are omitted. Since a level of the lower surfaces of the second pads 152 may be located lower than the upper surfaces of the insulating layer 164b and the insulating layer 364b, the solders 156 may be prevented from overflowing onto the upper surfaces of the insulating layer 164b and the insulating layer 364b, while being compressed vertically. Accordingly, the solders 156 may have a large contact area compared to their volumes, and the degree of integration and reliability of the electrical connection paths of the solders 156 may increase.

Meanwhile, referring to FIG. 1, the semiconductor package 500 according to an embodiment of the present disclosure may include an upper dummy chip 200 disposed on the rear surface (upper surface) of the semiconductor chip 100C. For example, the upper dummy chip 200 may include a semiconductor, such as silicon, or a metal substrate. In some embodiments, the upper dummy chip 200 may provide a heat dissipation function and/or an identification mark display region.

The upper dummy chip 200 may have a thickness T2 greater than a thickness T1a of the plurality of semiconductor chips 100A1, 100A2, and 100A3 and a thickness T1b of the semiconductor chip 100C. For example, the thickness T2 of the upper dummy chip 200 may be 200 μm or more, and the thickness T1a and the thickness T1b may be 100 μm or less.

The upper dummy chip 200 includes a lower bonding insulating layer 210 disposed on a lower surface of the upper dummy chip, and the semiconductor chip 100C includes an insulating layer 174 disposed on an upper surface thereof. The upper dummy chip 200 may be bonded to the rear surface (upper surface) of the semiconductor chip 100C by directly bonding the lower bonding insulating layer 210 and the insulating layer 174. In this manner, the upper dummy chip 200 and the semiconductor chip 100C may be bonded by inter-dielectric bonding of the lower bonding insulating layer 210 and the insulating layer 174. At least one from among the lower bonding insulating layer 210 and the insulating layer 174 may include a dielectric layer formed through a deposition process, but alternatively, it may include a natural oxide layer formed through a high temperature annealing process.

A width W2 (or area) of the upper dummy chip 200 may be the same as the width W1a (or area) of the plurality of semiconductor chips 100A1, 100A2, and 100A3 and the same as the width W1b (or area) of the semiconductor chip 100C, but is not limited thereto.

Referring to FIG. 1, the semiconductor package 500 according to an embodiment of the present disclosure may include a molding portion 180 sealing the plurality of semiconductor chips 100A1, 100A2, 100A3, and 100C and the upper dummy chip 200. For example, the molding portion 180 may include epoxy mold compound (EMC), etc.

An upper surface 200T of the upper dummy chip 200 is exposed from an upper surface 180T of the molding portion 180. The upper surface 200T of the upper dummy chip 200 may have a substantially flat coplanar surface with the upper surface 180T of the molding portion 180. These coplanar upper surfaces may be understood as upper surfaces obtained through a polishing process. In addition, a side surface of the molding portion 180 may have a substantially flat coplanar surface with a side surface of the semiconductor chip 300. These coplanar side surfaces may be understood as side surfaces obtained by the same cutting process.

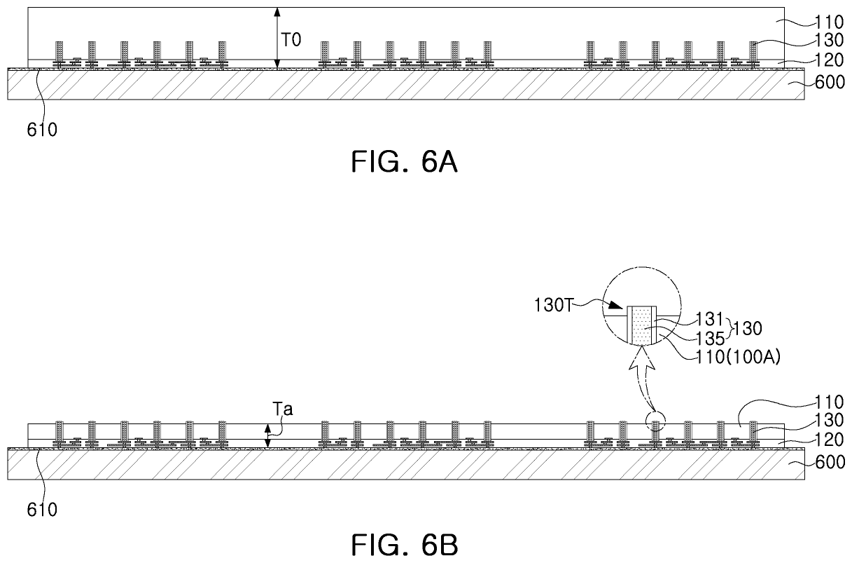

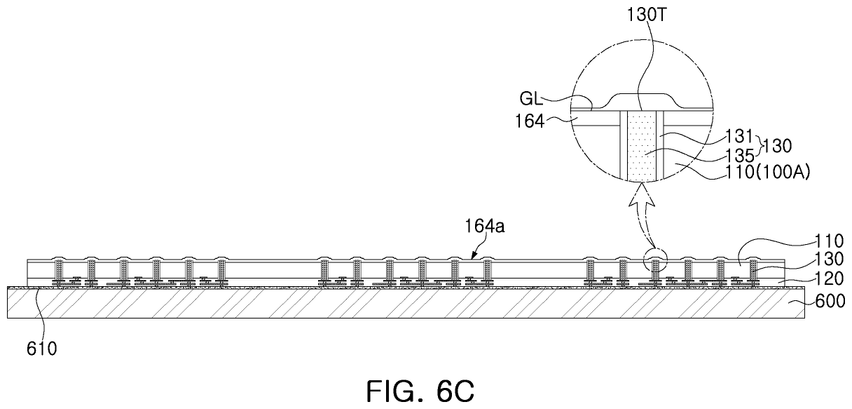

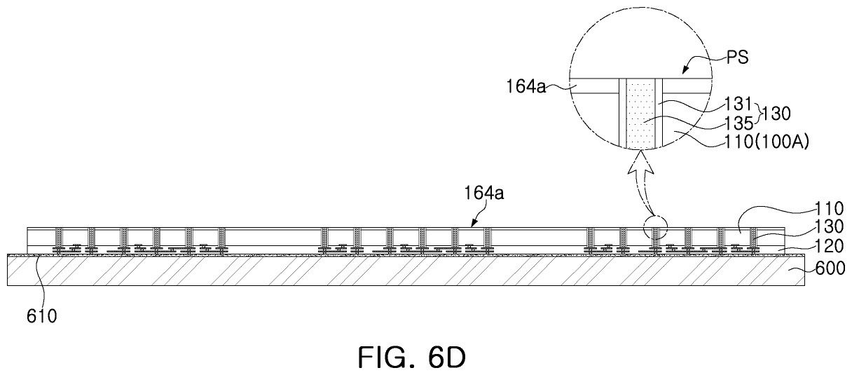

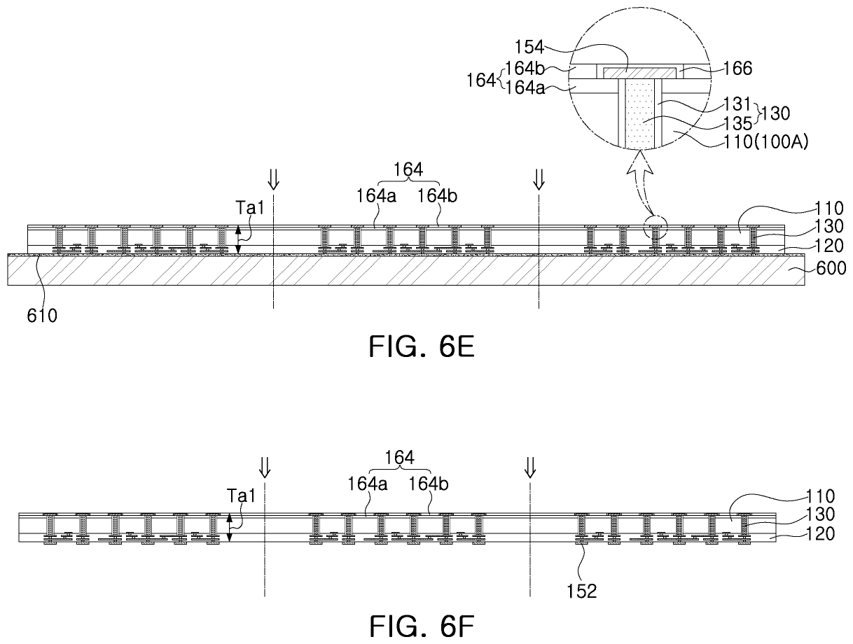

FIGS. 6A to 7C illustrate a method of manufacturing a semiconductor package according to an embodiment of the present disclosure. Accordingly, the semiconductor package 500 of FIG. 1 may be manufactured, but the semiconductor package 500 of FIG. 1 is not limited by the method of manufacturing a semiconductor package illustrated in FIGS. 6A to 7C.

Referring to FIGS. 6A to 6E, at least a portion of a semiconductor package according to an embodiment of the present disclosure may be manufactured by an operation of forming a device layer 120, a semiconductor substrate 110, an insulating layer 164, and a first pads 154.

Referring to FIG. 6A, the semiconductor substrate 110 for a plurality of semiconductor chips (e.g., the semiconductor chips 100A1, 100A2, 100A3, and 100C in FIG. 1) is bonded to a carrier substrate 600. For convenience of description, the semiconductor substrate 110 is illustrated as a wafer for including three semiconductor chips. A plurality of semiconductor chips may be formed as individual devices on an active surface of the semiconductor substrate 110. In addition, through-electrodes 130 extending into the interior of the semiconductor substrate 110 and the device layer 120 connected to the through-electrodes 130 may be formed on the active surface of the semiconductor substrate 110. In this manner, the semiconductor substrate 110 may be understood as being in a state in which a backside process has not been performed after completing a front process of the semiconductor chip. That is, since a grinding process has not been applied to the semiconductor substrate 110, the semiconductor substrate 110 may have a relatively large first thickness TO. The front surface (lower surface) of the semiconductor substrate 110, that is, the surface on which the device layer is formed, is bonded to face the carrier substrate 600. This bonding may be implemented by an adhesive layer 610, such as an ultraviolet (UV) curable film.

Referring to FIG. 6B, a grinding process is applied to the inactive surface of the semiconductor substrate 110 so that the first thickness TO of the semiconductor substrate 110 is reduced to the thickness Ta. In this grinding, an upper end 130T of the through-electrode 130 may be exposed from a ground surface of the semiconductor wafer. The upper end 130T may protrude from the surface of the semiconductor wafer due to a difference in etch rate. Through this process, the thickness of the semiconductor chip 100A may be reduced to a desire thickness (e.g., the thickness Ta). This thickness reduction process may be performed by an etch-back process, as well as by a grinding process, such as chemical mechanical polishing (CMP) process, or combinations thereof. In some embodiments, the thickness of the semiconductor substrate 110 may be reduced by performing a grinding process, and the through-electrode 130 may be sufficiently exposed by applying etch-back under appropriate conditions.

Referring to FIG. 6C, a rear insulating layer 164a may be formed on the semiconductor substrate 110 to cover the upper end 130T of the through-electrode 130 that is exposed. The rear insulating layer 164a may be used as a passivation layer. For example, the rear insulating layer 164a may include silicon nitride or silicon oxynitride.

Referring to FIG. 6D, the rear insulating layer 164a may be ground to expose the through-electrode 130. A grinding process may be performed up to a predetermined line GL (refer to FIG. 6C) so that the rear insulating layer 164a is partially removed and the through-electrode 130 is sufficiently exposed. Through this grinding process, the rear insulating layer 164a may have an upper surface substantially flat and coplanar with an upper surface of the through-electrode 130. In addition, a damaged portion of the upper end 130T of the through-electrode 130 may also be removed.

Referring to FIG. 6E, a first pads 154 and an insulating layer 164b surrounding the first pads 154 may be formed on the rear insulating layer 164a. Similar to the previous processes, the insulating layer 164b may be formed on the rear insulating layer 164a, and a plurality of cavities may be formed in the insulating layer 164b, a first pads 154 may be formed in a partial space of the plurality of cavities, and a margin portions 166 may be formed in a remaining space of the plurality of cavities. The margin portions 166 may be epoxy solders.

Referring to FIG. 6F, a second pads 152 may be formed on the front surface (lower surface) of the device layer 120. Like the first pads 154, the second pads 152 may be formed using a photolithography method. Thereafter, an underfill 162 (refer to FIG. 1) may be formed on the front surface (lower surface) of the device layer 120 to surround the second pads 152.

A formation order of the second pads 152 and the first pads 154 may vary depending on the embodiment. For example, the second pads 152 may be formed first, and then the first pads 154, the insulating layer 164b, and the margin portions 166 may be formed. Alternatively, the second pads 152 may be formed together when the device layer 120 is formed.

Referring to FIGS. 7A to 7C, the structure manufactured through FIGS. 6A to 6E may include a plurality of semiconductor chips (e.g., the semiconductor chips 100A1, 100A2, 100A3, and 100C in FIG. 1), and the plurality of semiconductor chips (e.g., the semiconductor chips 100A1, 100A2, 100A3, and 100C in FIG. 1) may be vertically stacked and connected to each other through the first pads 154 and the second pads 152.

Referring to FIG. 7A, a base structure 300W having a first pads 354 and a second pads 352 is prepared. For convenience of description, the base structure 300W is illustrated in a form for manufacturing three semiconductor packages and may include the three semiconductor chips 300 of FIG. 1. The base structure 300W may include an insulating layer 364 surrounding the first pads 354 at an upper end thereof. The insulating layer 364 may have an upper surface substantially flat and coplanar with the upper surfaces of the first pads 354. Connection bumps 370, such as solder balls, may be formed on the second pads 352 of the base structure 300W. In addition, in the present embodiment, although the base structure 300W is illustrated as a logic chip or memory chip electrically connecting the first pads 354 and the second pads 352, the base structure 300W may be an interposer having an internal circuit depending on the embodiment.

Referring to FIG. 7B, individualized semiconductor chips 100A1 are disposed on the base structure 300W. The semiconductor chips 100A1 may be semiconductor chips obtained in the operation illustrated in FIG. 6F. In this stacking process, pre-bonding may be performed by applying a certain pressure using a bonding tool (BT). Specifically, the second pads 152 of the first semiconductor chips 100A1 may be directly pre-bonded to the first pads 354 of the semiconductor chip 300, respectively, and similarly, the underfill 162 of the semiconductor chips 100A1 may be directly pre-bonded to the insulating layer 364 of the semiconductor chip 300.

Additional semiconductor chips 100A2 and 100A3 may be sequentially stacked, and semiconductor chips 100C may be disposed on the uppermost semiconductor chips (e.g., the semiconductor chips 100A3) (refer to FIG. 7C). With reference to FIGS. 7B-7C, the plurality of semiconductor chips 100A2, 100A3, and 100C may be pre-bonded to other semiconductor chips 100A1, 100A2, and 100A3 located therebelow. Specifically, the second pads 152 and the underfill 162 of each of the semiconductor chips 100A2, 100A3, and 100C may be directly pre-bonded to the first pads 154 and the insulating layer 164 of the semiconductor chips 100A1, 100A2, and 100A3 stacked immediately before, respectively. Thereafter, an annealing process may be performed, the underfill 162 and the insulating layer 164 may be directly bonded, and the second pads 152 and the first pads 154 may be bonded through plurality of solders. Thereafter, the upper dummy chip 200 may be disposed on the rear surface (upper surface) of the semiconductor chip 100C, and the rear surface (upper surface) of the upper dummy chip 200 may be polished.

Referring to FIG. 7C, the semiconductor package illustrated in FIG. 7B may be cut in a vertical direction. Accordingly, a plurality of semiconductor packages may be formed. Depending on the embodiment, the rear surface (upper surface) of the upper dummy chip 200 may include an identification mark or provide a space for disposing a heat sink.

FIG. 7D illustrates a structure 1000 in which semiconductor packages 500 are mounted on an interposer 1010 according to an embodiment of the present disclosure. For example, structure 1000 may be a 2.5-dimension structure.

A controller chip 1020 may be mounted on a central region of the interposer 1010 through at least one connection bump 1025, and a plurality of the semiconductor packages 500 may be arranged to surround the controller chip 1020 and may be mounted on an upper surface of the interposer 1010 through at least one connection bump 370. The controller chip 1020 may transmit a signal for controlling the plurality of semiconductor packages 500 to the plurality of semiconductor packages 500 through the interposer 1010, and the plurality of semiconductor packages 500 may also transmit a signal to the controller chip 1020 through the interposer 1010.

For example, the interposer 1010 may be implemented in a similar manner to that of the semiconductor chip 300 of FIG. 1, but unlike the semiconductor chip 300, the interposer 1010 may not include individual semiconductor devices and may include a silicon substrate, redistribution layers disposed on a front surface (lower surface) of the silicon substrate, and redistribution insulating layers disposed between the redistribution layers. The interposer 1010 may be mounted on the upper surface of a printed circuit board 1030 through at least one connection bump 1015. At least one connection bump 1035 may be disposed on a lower surface of the printed circuit board 1030.

A heat dissipation member 1040 may be disposed on upper surfaces of the controller chip 1020 and the plurality of semiconductor packages 500. For example, the heat dissipation member 1040 may include a heat slug, may include a material having greater thermal conductivity than air (e.g., gold (Au), silver (Ag), copper (Cu), iron (Fe), graphite, and graphene), and may directly contact the upper surfaces of the controller chip 1020 and the plurality of semiconductor packages 500 through a thermal interface material (TIM) layer.

A semiconductor package according to an embodiment of the present disclosure may have an improved degree of integration of electrical connection paths provided by a plurality of pads or improved reliability of the electrical connection paths.

While non-limiting example embodiments have been described above and shown in the drawings, it will be apparent to those skilled in the art that modifications and variations could be made without departing from the scope of the present disclosure.

What is claimed is:

1. A semiconductor package comprising:
an insulating layer;
first pads respectively surrounded by the insulating layer;
second pads electrically connected to the first pads;
solders between and connected to the first pads and the second pads, and respectively surrounded by the insulating layer; and
margin portions comprising an insulating material, surrounding the solders, and respectively surrounded by the insulating layer.

2. The semiconductor package of claim 1, wherein the margin portions respectively surround the solders and separate the first pads from the insulating layer.

3. The semiconductor package of claim 1, wherein the insulating material of the margin portions is different from an insulating material of the insulating layer.

4. The semiconductor package of claim 3, wherein the insulating material of the margin portions comprises an epoxy resin, and
wherein the insulating layer comprises at least one from among a build-up film, photosensitive polyimide (PSPI), and a photo imagable dielectric (PID).

5. The semiconductor package of claim 3, wherein the margin portions further comprises solder particles.

6. The semiconductor package of claim 1, further comprising an underfill surrounding each of the second pads.

7. The semiconductor package of claim 6, wherein the underfill is spaced apart from the solders.

8. The semiconductor package of claim 6, wherein a thickness of each of the second pads is greater than a thickness of each of the first pads.

9. The semiconductor package of claim 6, wherein the underfill is on an upper surface of the insulating layer, and
wherein a level of lower surfaces of the second pads is lower than a level of the upper surface of the insulating layer.

10. The semiconductor package of claim 1, wherein each of the first pads comprises copper or a copper alloy,
wherein each of the second pads comprises copper or a copper alloy, and
wherein the solders are in direct contact with the copper or copper alloy of the first pads and are in direct contact with the copper or copper alloy of the second pads.

11. The semiconductor package of claim 1, further comprising semiconductor chips,
wherein the insulating layer, the first pads, and the second pads are between the semiconductor chips.

12. The semiconductor package of claim 11, wherein one of the semiconductor chips comprises:
a semiconductor substrate;
a device layer comprising an interconnection structure, the device layer on a front surface of the semiconductor substrate;
through-electrodes penetrating through the semiconductor substrate and electrically connected to the first pads; and
a rear insulating layer on a rear surface of the semiconductor substrate,
wherein the insulating layer is on a rear surface of the rear insulating layer.

13. The semiconductor package of claim 11, wherein one of the semiconductor chips comprises:
a semiconductor substrate; and
a device layer comprising an interconnection structure, the device layer on a front surface of the semiconductor substrate,
wherein the interconnection structure comprises:
an interconnection layer; and
a conductive pattern electrically connecting the interconnection layer to the second pads, and
wherein the conductive pattern is thicker than the interconnection layer.

14. A semiconductor package comprising:
an insulating layer;
first pads respectively surrounded by the insulating layer;
second pads electrically connected to the first pads;
solders between and connected to the first pads and the second pads, and respectively surrounded by the insulating layer; and
an underfill on an upper surface of the insulating layer and surrounding each of the second pads,
wherein a level of lower surfaces of the second pads is lower than a level of the upper surface of the insulating layer.

15. The semiconductor package of claim 14, wherein the underfill is spaced apart from the solders, and
wherein a thickness of each of the second pads is greater than a thickness of each of the first pads.

16. The semiconductor package of claim 15, further comprising semiconductor chips,
wherein the insulating layer, the first pads, and the second pads are between the semiconductor chips.

17. The semiconductor package of claim 16, wherein each of the first pads comprises copper or a copper alloy,
wherein each of the second pads comprises copper or a copper alloy, and
wherein the solders are in direct contact with the copper or copper alloy of the first pads and are in direct contact with the copper or copper alloy of the second pads.

18. A semiconductor package comprising:
semiconductor chips;
an insulating layer between the semiconductor chips;
first pads respectively surrounded by the insulating layer;
epoxy solders surrounded by the insulating layer and surrounding each of the first pads, the epoxy solders comprising solder particles and an epoxy resin;
an underfill between the semiconductor chips; and
second pads surrounded by the underfill and compressing the epoxy solders on the first pads.

19. The semiconductor package of claim 18, wherein each of the epoxy solders comprises an in-between region between the first pads and the second pads, and a margin region surrounding the in-between region, and
wherein a density of the solder particles in the in-between region is higher than a density of the solder particles in the margin region.

20. The semiconductor package of claim 19, wherein the underfill is on an upper surface of the insulating layer, and
wherein a level of lower surfaces of the second pads is lower than a level of the upper surface of the insulating layer.
